(19) United States
(12) Patent Application Publication
(10) Pub. No.: US 2008/0315417 A1
(43) Pub. Date: Dec. 25, 2008

(54) CHIP PACKAGE

(75) Inventors: Geng-Shin Shen, Tainan County (TW); Chun-Ying Lin, Tainan County (TW); Shih-Wen Chou, Tainan County (TW)

Correspondence Address: J C PATENTS, INC., 4 VENTURE, SUITE 250, IRVINE, CA, 92618, US

(73) Assignees: CHIPMOS TECHNOLOGIES INC., Hsinchu (TW); CHIPMOS TECHNOLOGIES (BERMUDA) LTD., Hamilton HM12 (BM)

(21) Appl. No.: 12/201,231

(22) Filed: Aug. 29, 2008

Related U.S. Application Data
(63) Continuation-in-part of application No. 11/302,736, filed on Dec. 13, 2005, now Pat. No. 7,436,074.

(30) Foreign Application Priority Data
Jul. 14, 2005 (TW) 94123850

(51) Int. Cl. H01L 23/498

(52) U.S. Cl. 257/738; 257/E23.069

(57) ABSTRACT

A chip package includes a patterned conductive layer, a first solder resist layer, a second solder resist layer, a chip, bonding wires and a molding compound. The patterned conductive layer has a first surface and a second surface opposite to each other. The first solder resist layer is disposed on the first surface. The second solder resist layer is disposed on the second surface, wherein a part of the second surface is exposed by the second solder resist layer. The chip is disposed on the first solder resist layer, wherein the first solder resist layer is disposed between the patterned conductive layer and the chip. The bonding wires are electrically connected to the chip and the patterned conductive layer exposed by the second solder resist layer. The molding compound encapsulates the pattern conductive layer, the first solder resist layer, the second solder resist layer, the chip and the bonding wires.

### CROSS-REFERENCE TO RELATED APPLICATION

This is a continuation-in-part application of patent application Ser. No. 11/302,736 filed on Dec. 13, 2005, which claims the priority benefit of Taiwan patent application serial no. 94123850, filed Jul. 14, 2005. The entirety of each of the above-mentioned patent applications is hereby incorporated by reference herein and made a part of this specification.

### BACKGROUND OF THE INVENTION

1. Field of the Invention

The present invention relates to a chip package. More particularly, the present invention relates to a chip package having small thickness.

2. Description of Related Art

In the industry of the semiconductor, the production of integrated circuits (IC) can be mainly divided into three stages: IC design, IC fabrication process and IC package.

During the IC fabrication process, a chip is fabricated by the steps such as wafer process, IC formation and wafer sawing. A wafer has an active surface, which generally means the surface that a plurality of active devices is formed thereon. After the IC within the wafer is completed, a plurality of bonding pads are further formed on the active surface of the wafer so that the chip formed by wafer sawing can be electrically connected to a carrier through the bonding pads. The carrier may be a lead frame or a circuit board. The chip can be electrically connected to the carrier by wire bonding or flip chip bonding, so that the bonding pads on the chip are electrically connected to connecting pads of the carrier, thereby forming a chip package structure.

In general, in the manufacturing method of the conventional circuit board, a core dielectric layer is necessarily required, the patterned circuit layer and the patterned dielectric layer are inter-stacked on the core dielectric layer in a fully additive process, semi-additive process, subtractive process or other suitable process. Accordingly, the core dielectric layer may take a major proportion in the entire thickness of the circuit board. Therefore, if the thickness of the core dielectric layer can not be reduced effectively, it would be a big obstacle in reducing the thicknesses of the chip package.

### SUMMARY OF THE INVENTION

The present invention is to provide a chip package with thinner thickness.

As embodied and broadly described herein, the present invention provides a chip package including a patterned conductive layer, a first solder resist layer, a second solder resist layer, a chip, a plurality of bonding wires and a molding compound. The patterned conductive layer has a first surface and a second surface opposite to each other. The first solder resist layer is disposed on the first surface. The second solder resist layer is disposed on the second surface, wherein a part of the second surface is exposed by the second solder resist layer. The chip is disposed on the first solder resist layer, wherein the first solder resist layer is disposed between the patterned conductive layer and the chip. The bonding wires are electrically connected to the chip and the patterned conductive layer exposed by the second solder resist layer. The molding compound encapsulates the pattern conductive layer, the first solder resist layer, the second solder resist layer, the chip and the bonding wires.

According to an embodiment of the present invention, the patterned conductive layer comprises a plurality of leads.

According to an embodiment of the present invention, the first solder resist layer has a first opening, the chip has an active surface, a rear surface opposite to the active surface and a plurality bonding pads disposed on the active surface, and the bonding pads are exposed by the first opening.

According to an embodiment of the present invention, the second solder resist layer has a plurality of second openings.

According to an embodiment of the present invention, the chip package further comprises a plurality of outer terminals disposed in the second openings, wherein the outer terminals are electrically connected to the patterned conductive layer.

According to an embodiment of the present invention, the outer terminals comprise solder balls.

According to an embodiment of the present invention, the chip package further comprises an adhesive layer disposed between the first solder resist layer and the chip.

According to an embodiment of the present invention, the adhesive layer comprises a B-staged adhesive layer.

According to an embodiment of the present invention, the chip is partially encapsulated by the molding compound.

According to an embodiment of the present invention, the chip is entirely encapsulated by the molding compound.

In summary, since the chip package of the present invention has no core dielectric layer, the chip package of the present invention has thinner thickness than the conventional chip package.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1H are cross-sectional views schematically illustrating the manufacturing process of the chip package according to an embodiment of the present invention.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

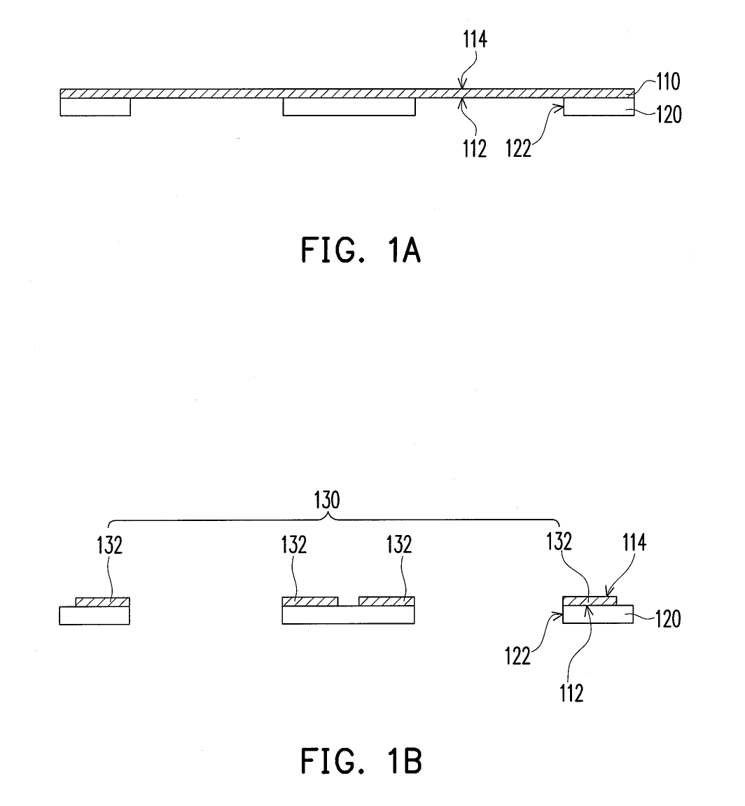

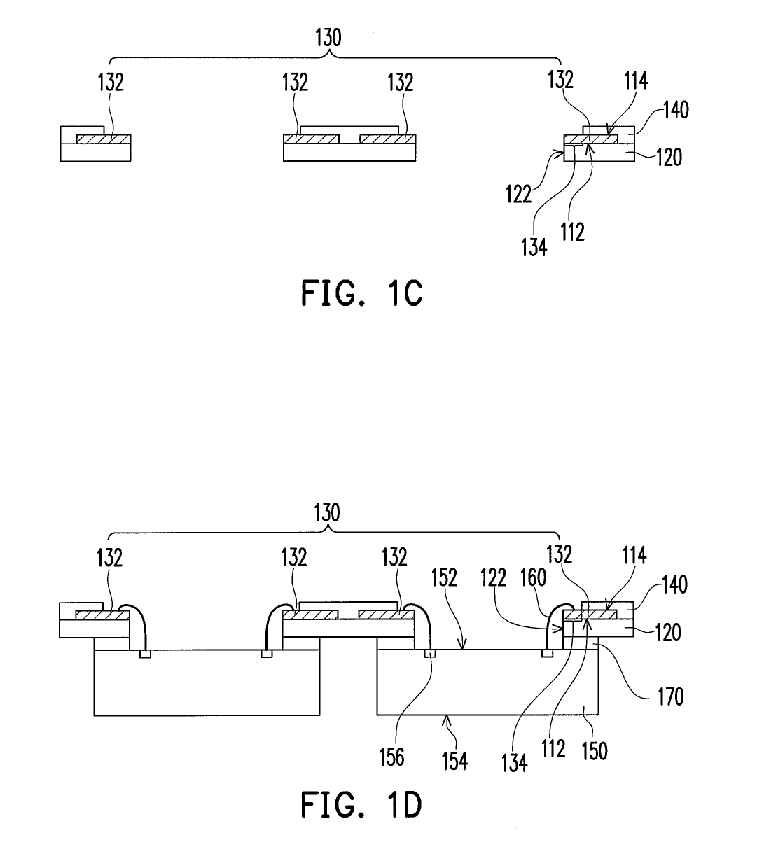

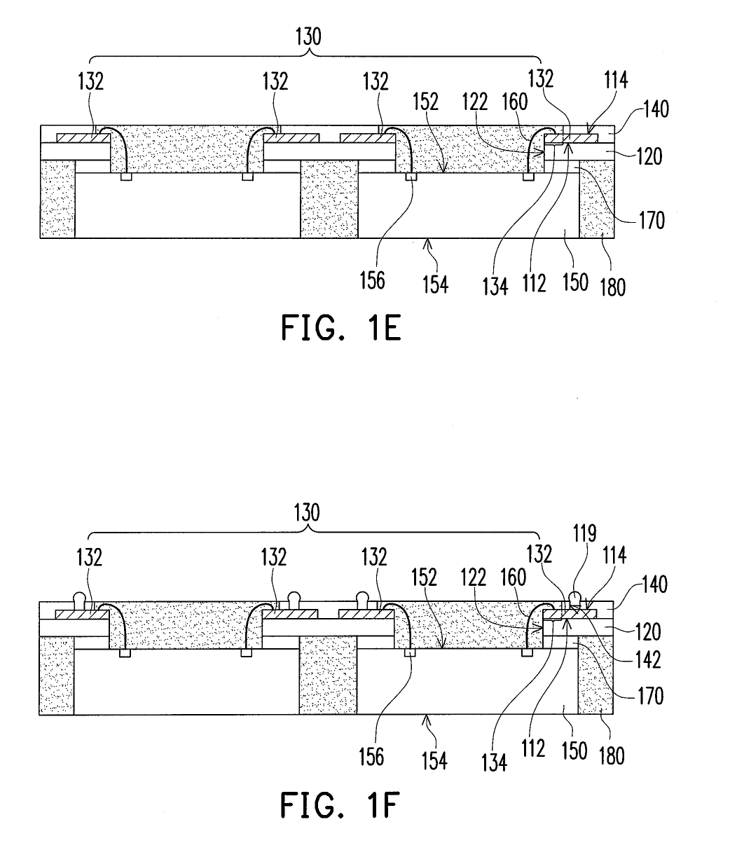

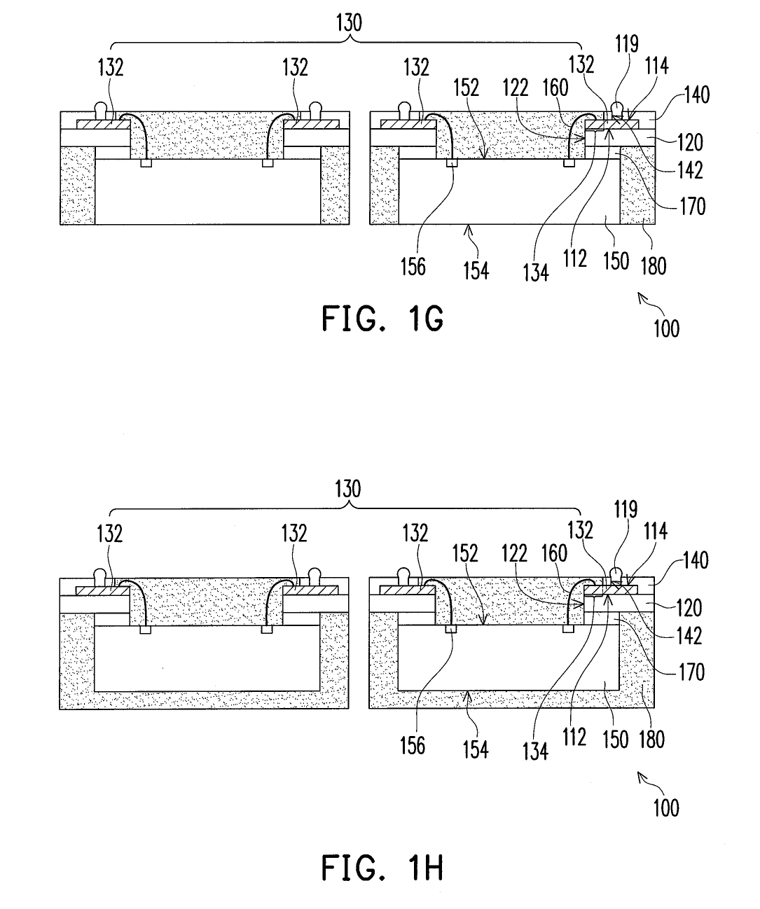

FIG. 1A to FIG. 1H are cross-sectional views schematically illustrating the manufacturing process of the chip package according to an embodiment of the present invention. Referring to FIG. 1A, a conductive layer 110 and a first solder resist layer 120 are provided, wherein the conductive layer 110 has a first surface 112 and a second surface 114 opposite to each other, and the first solder resist layer 120 has a plurality of first openings 122. Additionally, the first solder resist layer 120 is disposed on the first surface 112 of the conductive layer 110. In a preferred embodiment, a brown oxidation or a black oxidation process can further be performed on the patterned conductive layer 130 to improve the surface roughness of the patterned conductive layer 130. Accordingly, the combination between the patterned conductive layer 130 and the first solder resist layer 120 or the patterned conductive layer 130 and the second solder resist layer 140 is improved.

In the present embodiment, the first solder resist layer 120 may be provided by attaching a solid solder resist film onto the first surface 112 of the conductive layer 110 first, and the solid solder resist film may be patterned to form the first solder resist layer 120 before or after being attached onto the conductive layer 110. In an alternative embodiment, the first solder resist layer 120 may be formed by coated a liquid solder resist coating on the first surface 112 of the conductive layer 110 first, and the liquid solder resist film should be cured and patterned to form the first solder resist layer 120 after being coated on the first surface 112 of the conductive layer 110.

Referring to FIG. 1B, the conductive layer 110 is then patterned to form a patterned conductive layer 130 through a photolithography and etching process, wherein the patterned conductive layer 130 has a plurality of leads 132. It is noted that sequence of the patterning processes for forming the conductive layer 110 and the first solder resist layer 120 is not limited in the present invention.

Referring to FIG. 1C, a second solder resist layer 140 is formed on the second surface 114 of the patterned conductive layer 130, wherein a part of the second surface 114 is exposed by the second solder resist layer 140. In other words, a plurality of first bonding pads 134 are defined by the second solder resist layer 140 formed on a part of the second surface 114. The second solder resist layer 140 may be formed by molding process, printing process, or film attaching process. In a preferred embodiment, a plating process may be performed so as to form plating conductive layer (not shown) on the first bonding pads 134. The plating conductive layer may be a Ni/Au stacked layer, or other suitable metal layers.

Referring to FIG. 1D, a plurality of chips 150 are adhered to the first solder resist layer 120 and a plurality of bonding wires 160 are then formed to connect the first bonding pads 134 and the chips 150, wherein each chip 150 has an active surface 152, a rear surface 154 opposite to the active surface 152 and a plurality of second bonding pads 156 disposed on the active surface 152, and the second bonding pads 156 are exposed by one first opening 122. Each chip 150 is adhered the first solder resist layer 120 by a adhesive layer 170 between the chip 150 and the first solder resist layer 120 such that the first solder resist layer 120 is between the patterned conductive layer 130 and each chip 150.

In the present embodiment, the bonding wires 160 are formed by a wire bonding process, such that each bonding wire 160 is electrically connected between a first bonding pad 134 and a second bonding pad 156. The bonding wires 160 is, for example, Au wires.

In the present embodiment, the adhesive layer 170 is a B-staged adhesive layer, for example. The B-staged adhesive layer can be obtained from 8008 or 8008HT of ABLESTIK. Additionally, the B-staged adhesive layer can also be obtained from 6200, 6201 or 6202C of ABLESTIK, or obtained from SA-200-6, SA-200-10 provided by HITACHI Chemical CO., Ltd. In an embodiment of the present invention, the B-staged adhesive layer 170 is formed on the active surface of a wafer. When the wafer is cut, a plurality of chip 150 having the adhesive layer 170 on the active surface 152 thereof is obtained. Therefore, the B-staged adhesive layer 170 is favorable to mass production. Additionally, the B-staged adhesive layer 170 may be formed by spin-coating, printing, or other suitable processes. More specifically, the adhesive layer 170 is formed on the active surface 152 of the chip 150 in advance. Specifically, a wafer having a plurality of chip 150 arranged in an array is first provided. Then, a two-stage adhesive layer is formed over the active surface 152 of the chip 150 and is partially cured by heating or UV irradiation to form the B-staged adhesive layer 170. Sometimes, the B-staged adhesive layer 170 could be formed on the first solder resist layer 120 before the chip 150 being attached on the first solder resist layer 120.

In the present embodiment, the B-staged adhesive layer 170 is fully cured after the chip 150 being attached to the first solder resist layer 120 or later by a post cured or being encapsulated by the molding compound 180.

Referring to FIG. 1E, a molding compound 180 encapsulating the pattern conductive layer 130, the first solder resist layer 120, the second solder resist layer 140, the chip 150 and the bonding wires 160 is formed. The material of the molding compound 180 is, for example, epoxy resin.

Referring to FIG. 1F, a plurality of second openings 142 are formed in the second solder resist layer 140 so as to expose a part of the second surface 114 of the conductive layer 110. A plurality of outer terminals 190 are then formed in the second openings 142 so as to electrically connect to the patterned conductive layer 130. The outer terminals, for example, are solder balls. It is noted that the second openings 142 in the second solder resist layer 140 may be formed simultaneously when the second solder resist layer 140 is formed on the second surface 114 of the patterned conductive layer 130.

Referring to FIG. 1G, the structure shown in FIG. 1F is singularized for forming a plurality of chip packages 100. It is noted that the pattern conductive layer 130 is not extended to the side wall W of the chip package 100, so that the pattern conductive layer 130 is not exposed at the side wall W of the chip package 100. Although the chip 150 is partially encapsulated by the molding compound 180 and the rear surface 154 is exposed, it is clear that the chip 150 can be entirely encapsulated by the molding compound 180, as shown in FIG. 1H.

As shown in FIG. 1F, the chip package 100 of the present invention mainly includes a patterned conductive layer 130, a first solder resist layer 120, a second solder resist layer 140, a chip 150, a plurality of bonding wires 160 and a molding compound 180. The patterned conductive layer 130 has a first surface 112 and a second surface 114 opposite to each other. The first solder resist layer 120 is disposed on the first surface 112. The second solder resist layer 140 is disposed on the second surface 114, wherein a part of the second surface 114 is exposed by the second solder resist layer 140. The chip 150 is disposed on the first solder resist layer 120, wherein the first solder resist layer 120 is disposed between the patterned conductive layer 130 and the chip 150. The bonding wires 160 are electrically connected to the chip 150 and the patterned conductive layer 130 exposed by the second solder resist layer 140. The molding compound 180 encapsulates the pattern conductive layer 130, the first solder resist layer 120, the second solder resist layer 140, the chip 150 and the bonding wires 160.

Compared with the conventional chip package having circuit substrate, the chip package 100 of the present invention has no core dielectric layer and has thinner thickness. Additionally, the production cost is lowered and the production efficiency is improved in the present invention.

It will be apparent to those skilled in the art that various modifications and variations may be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A chip package, comprising:
a patterned conductive layer, having a first surface and a second surface opposite to each other;
a first solder resist layer, disposed on the first surface;
a second solder resist layer, disposed on the second surface, wherein a part of the second surface is exposed by the second solder resist layer;
a chip, disposed on the first solder resist layer, wherein the first solder resist layer is disposed between the patterned conductive layer and the chip;
a plurality of bonding wires, electrically connected to the chip and the patterned conductive layer exposed by the second solder resist layer; and
a molding compound, encapsulating the pattern conductive layer, the first solder resist layer, the second solder resist layer, the chip and the bonding wires.

2. The chip package as claimed in claim 1, wherein the patterned conductive layer comprises a plurality of leads.

3. The chip package as claimed in claim 1, wherein the first solder resist layer has a first opening, the chip has an active surface, a rear surface opposite to the active surface and a plurality bonding pads disposed on the active surface, and the bonding pads are exposed by the first opening.

4. The chip package as claimed in claim 1, wherein the second solder resist layer has a plurality of second openings.

5. The chip package as claimed in claim 4, further comprising a plurality of outer terminals disposed in the second openings, wherein the outer terminals are electrically connected to the patterned conductive layer.

6. The chip package as claimed in claim 5, wherein the outer terminals comprise solder balls.

7. The chip package as claimed in claim 1, further comprising an adhesive layer disposed between the first solder resist layer and the chip.

8. The chip package as claimed in claim 7, wherein the adhesive layer comprises a B-staged adhesive layer.

9. The chip package as claimed in claim 1, wherein the chip is partially encapsulated by the molding compound.

10. The chip package as claimed in claim 1, wherein the chip is entirely encapsulated by the molding compound.
